(19) United States
(12) Patent Application Publication
(10) Pub. No.: US 2022/0004180 A1
(43) Pub. Date: Jan. 6, 2022

(54) AUTOMATIC DETECTING DEVICE AND AUTOMATIC DETECTING METHOD OF MANUFACTURING EQUIPMENT

(71) Applicant: UNITED MICROELECTRONICS CORP., Hsinchu (TW)

(72) Inventor: Ching-Pei LIN, Hsinchu County (TW)

(21) Appl. No.: 16/988,747

(22) Filed: Aug. 10, 2020

(30) Foreign Application Priority Data
Jul. 3, 2020 (CN) 202010635524.3

(51) Int. Cl. G05B 23/02; H01L 21/67

(52) U.S. Cl. CPC G05B 23/0283; H01J 37/32935; H01L 21/67276

(57) ABSTRACT

An automatic detecting device and an automatic detecting method of a manufacturing equipment are provided. The automatic detecting method of the manufacturing equipment includes the following steps. A detection curve of the manufacturing equipment executing several recipe steps is obtained. The detection curve is aligned to the recipe steps, such that the detection curve is divided into several process segments. At least one peak or at least one valley in each of the process segments is searched to obtain several sub-step segments. According to the sub-step segments, a Fault Detection Classification analysis (FDC) is performed to obtain an analysis result. Based on the analysis result, a predict health information of the manufacturing equipment is outputted.

This application claims the benefit of People's Republic of China application Serial No. 202010635524.3, filed Jul. 3, 2020, the disclosure of which is incorporated by reference herein in its entirety.

### TECHNICAL FIELD

The disclosure relates in general to an automatic detecting device and an automatic detecting method, and more particularly to an automatic detecting device and an automatic detecting method of a manufacturing equipment.

### BACKGROUND

With the rapid development of semiconductor technology, the complexity and precision of the process continue to increase. In the semiconductor process, after analyzing various detection information of manufacturing equipment, the health information can be predicted. If the predicted health information of the manufacturing equipment is found to be unsatisfactory, it needs to be adjusted as soon as possible to avoid mass production of defective products.

Traditionally, manpower is used to analyze the detection information for abnormalities in each recipe step. However, this method must consume considerable manpower. Moreover, with the improvement of process precision, the detection in recipe steps is too rough, and it is impossible to accurately analyze the true cause of the abnormality.

### SUMMARY

The disclosure is directed to an automatic detecting device and an automatic detecting method of a manufacturing equipment. The recipe step is further subdivided into several sub-steps to extract more features, so that the accuracy of Fault Detection Classification analysis (FDC) is improved, and then more predictive Prognostic and Health Management (PHM) and Virtual Metrology (VM) are achieved.

According to one embodiment, an automatic detecting method of a manufacturing equipment. The automatic detecting method of the manufacturing equipment includes the following steps. A detection curve of the manufacturing equipment executing a plurality of recipe steps is obtained. The detection curve is aligned to the recipe steps, such that the detection curve is divided into a plurality of process segments. At least one peak or at least one valley in each of the process segments is searched to obtain a plurality of sub-step segments. A Fault Detection Classification analysis (FDC) is performed according to the sub-step segments, to obtain an analysis result. A predict health information of the manufacturing equipment is outputted based on the analysis result.

According to another embodiment, an automatic detecting device of a manufacturing equipment is provided. The automatic detecting device includes a data collection unit, a mapping unit, a subdivision unit, an analyzing unit and an outputting unit. The data collection unit is configured to obtain a detection curve of the manufacturing equipment executing a plurality of recipe steps. The mapping unit is configured to align the detection curve to the recipe steps, such that the detection curve is divided into a plurality of process segments. The subdivision unit is configured to search at least one peak or at least one valley in each of the process segments, to obtain a plurality of sub-step segments. The analyzing unit is configured to perform a Fault Detection Classification analysis (FDC), according to the sub-step segments, to obtain an analysis result. The outputting unit is configured to output a predict health information of the manufacturing equipment based on the analysis result.

### BRIEF DESCRIPTION OF THE DRAWINGS

FIG. 1 shows a schematic diagram of an automatic detecting device of a manufacturing equipment according to an embodiment.

FIG. 2 shows a flowchart of an automatic detecting method of the manufacturing equipment according to an embodiment.

FIG. 3 illustrates a schematic diagram of a detection curve according to an embodiment.

FIGS. 4A to 4H illustrate various track types according to an embodiment.

FIGS. 5A to 5D illustrate process segments of the detection curve.

FIG. 6 shows a detailed flowchart of step S140.

FIG. 7 shows a schematic diagram of the detection curve of FIG. 3 subdivided into sub-step segments.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

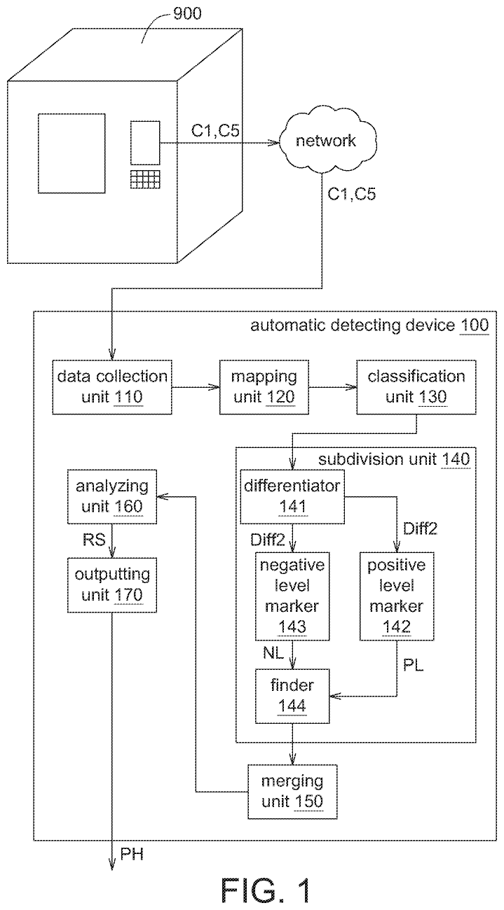

Please refer to FIG. 1, which shows a schematic diagram of an automatic detecting device 100 of a manufacturing equipment 900 according to an embodiment. The manufacturing equipment 900 is, for example, an etching chamber, a chemical vapor deposition chamber, or a sputtering chamber, etc. The manufacturing equipment 900 executes several recipe steps through a series of parameter settings. The parameter settings are, for example, “heat up to 500 degrees”, “turn on the plasma”, “vacuum” etc. During the execution of each of the recipe steps, various detectors can continuously monitor various values, such as monitoring gas flow value, pressure value, gas concentration value, temperature value, target weight value, light wavelength value, etc. During the execution of each of the recipe steps, these values have ideal corresponding changes. By observing the changes in these values, whether the manufacturing equipment 900 executes the recipe steps correctly can be known. For example, once it is detected that the temperature value raises too fast, the target thickness value decreases too slowly, or other error conditions occur, it means that manufacturing equipment 900 needs to be further adjusted. The above method is called Fault Detection and Classification (FDC). Through the detection and analysis of process errors, it can obtain the predicted health information of the manufacturing equipment and estimate the product yield to achieve Prognostic and Health Management (PHM) and Virtual Metrology (VM).

The automatic detecting device 100 of this embodiment can further subdivide the recipe step into several sub-steps to extract more features, so that the accuracy of the Fault Detection and Classification (FDC) can be improved, and the Prognostic and Health Management (PHM) and the Virtual Metrology (VM) can be more efficiently achieved.

The automatic detecting device 100 includes a data collection unit 110, a mapping unit 120, a classification unit 130, a subdivision unit 140, a merging unit 150, an analyzing unit 160 and an outputting unit 170. The data collection unit 110 is, for example, a wired network port, or a wireless network transmission module. The mapping unit 120, the classification unit 130, the subdivision unit 140, the merging unit 150, the analyzing unit 160 are, for example, a circuit, a chip, a circuit board, a plurality of program codes or a storage device for storing codes. The outputting unit 170 is, for example, a display screen or a printer. The automatic detecting device 100 further subdivides the recipe step into several sub-steps through the subdivision unit 140 to extract more features. The following describes the operation of the above components in detail through a flowchart.

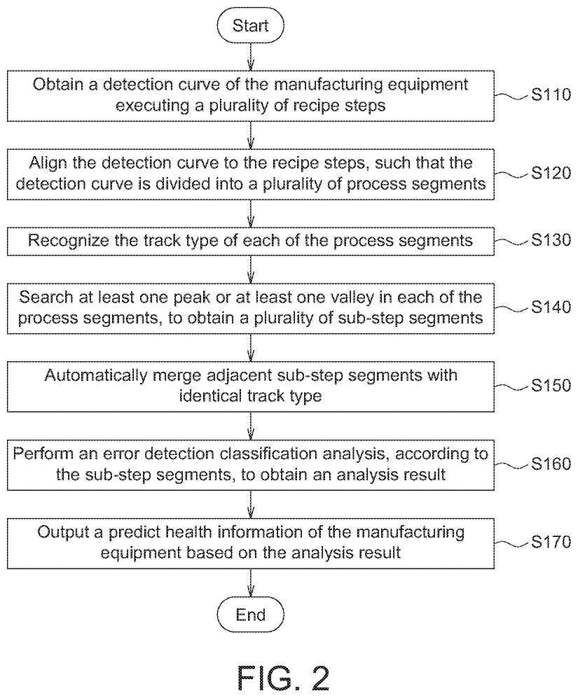

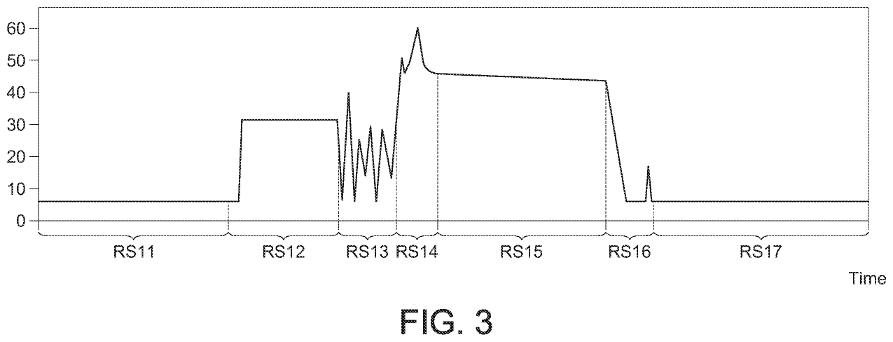

Please refer to FIG. 2, which shows a flowchart of an automatic detecting method of the manufacturing equipment 900 according to an embodiment. In step S110, the data collection unit 110 obtains a detection curve C1 of the manufacturing equipment 900 executing several recipe steps. Please refer to FIG. 3, which illustrates a schematic diagram of the detection curve C1 according to an embodiment. In the example in FIG. 3, the manufacturing equipment 900 executes several recipe steps according to the established parameter settings, and continuously detects various values as the recipe steps are executed. The detection curve C1 is an example of one of the detection values. The detection curve C1 is, for example, a curve obtained during the manufacturing process of a batch of wafers. Or, the detection curve C1 is, for example, the average curve obtained during the manufacturing process of multiple batches of wafers.

Next, in step S120, the mapping unit 120 aligns the detection curve C1 to the recipe steps, such that the detection curve C1 is divided into a plurality of process segments RS11, RS12, RS13, RS14, RS15, RS16, RS17. In this step, the mapping unit 120 aligns, for example, the starting point of the process segment RS11 to the starting point of the parameter setting according to the execution times of the parameter settings. Alternatively, for example, the mapping unit 120 aligns the starting points of the process segments RS11 to RS17 to the starting points of the respective parameter settings according to the execution times of the parameter settings. In this way, the detection curve C1 can be divided into the process segments RS11 to RS17.

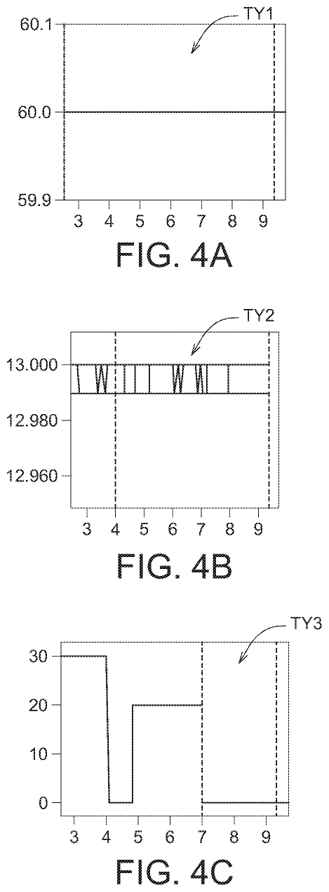

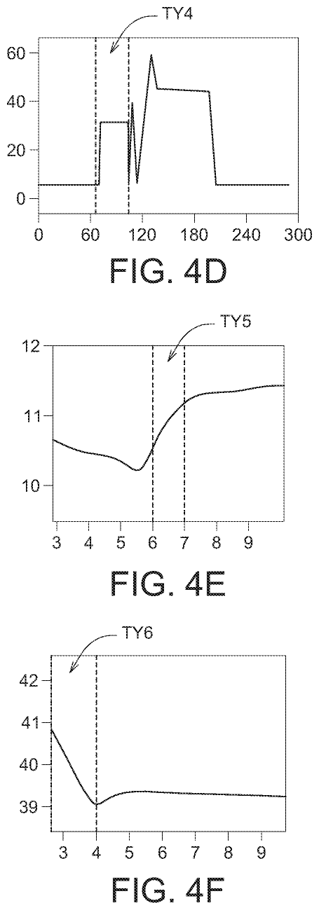

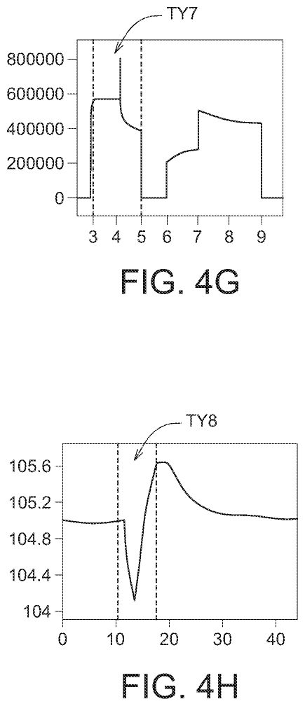

Then, in step S130, the classification unit 130 recognizes the track type of each of the process segments RS11 to RS17. For example, please refer to FIGS. 4A to 4H, which illustrate various track types TY1 to TY8 according to an embodiment. In order to avoid confusion between multiple lines, each of FIGS. 4A to 4H shows one curve obtained during the manufacturing process of only one batch of wafers. As shown in FIG. 4A, the track type TY1 is a constant track, and its value is substantially constant at a certain value. As shown in FIG. 4B, the track type TY2 is a fluctuating track, and its value keeps jumping, without obvious rising, falling, peak, valley. As shown in FIG. 4C, the track type TY3 is a zero-point track, and its value is essentially at the lowest value of the detection curve C1. As shown in FIG. 4D, the track type TY4 is a process processing track whose end is not fixed (that is, the end of the track of a batch of wafers is at 100, but the ends of the tracks of other batches of wafers is at 120, 105, 110, etc.), so it is considered that it is performing deposition, etching and other procedures. As shown in FIG. 4E, the track type TY5 is an ascending track, and its value gradually increases. As shown in FIG. 4F, the track type TY6 is a descending track, and its value gradually decreases. As shown in FIG. 4G, the track type TY7 is a regional peak track, and its value presents at least one peak. As shown in FIG. 4H, the track type TY8 is a regional valley track, and its value presents at least one valley. The classification unit 130 can use artificial intelligence recognition algorithms to identify various track types TY1 to TY8 for each of the process segments RS11 to RS17. In this embodiment, the above track types TY1 to TY8 can be further subdivided to improve the detection accuracy.

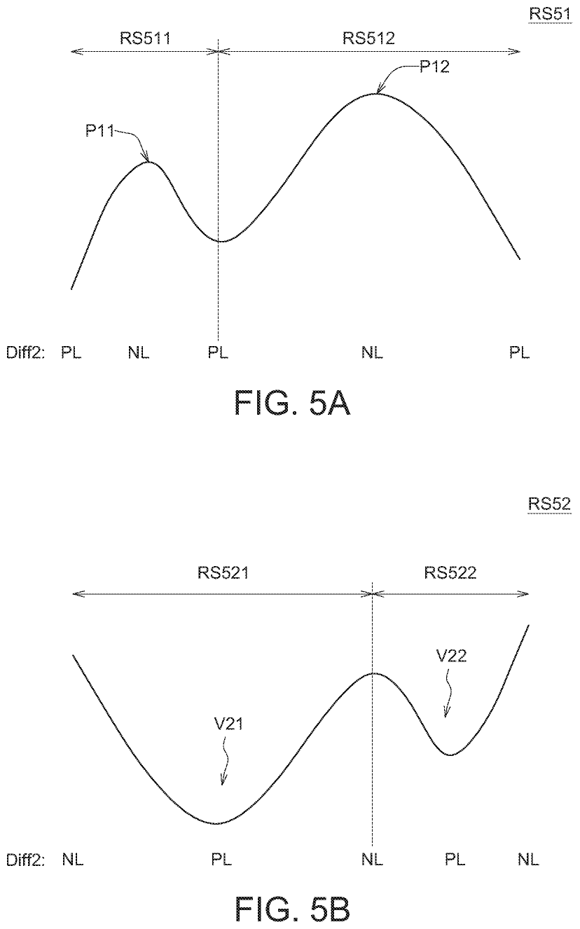

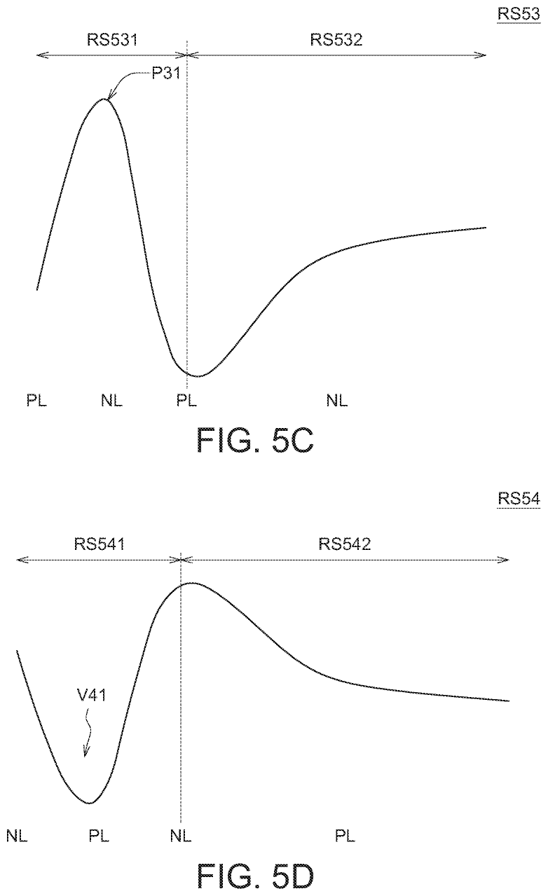

Next, in step S140, the subdivision unit 140 searches at least one peak or at least one valley in each of the process segment (for example, the process segment RS14 in FIG. 3) to obtain several sub-step segments. Please refer to FIGS. 5A to 5D, which illustrate the process segments RS51 to RS54 of the detection curve C5 (shown in FIG. 1). As shown in FIG. 5A, the subdivision unit 140 may search out a peak P11 and a peak P12 in the example process segment RS51, and then obtain two sub-step segments RS511 and RS512. As shown in FIG. 5B, the subdivision unit 140 may search out a valley V21 and a valley V22 in the example process segment RS52, and then obtain two sub-step segments RS521, RS522. As shown in FIG. 5C, the subdivision unit 140 may search out a peak P31 in the example process segment RS53, and then obtain two sub-step segments RS531, RS532. As shown in FIG. 5D, the subdivision unit 140 may search out a valley V41 in the example process segment RS54, and then obtain two sub-step segments RS541, RS542.

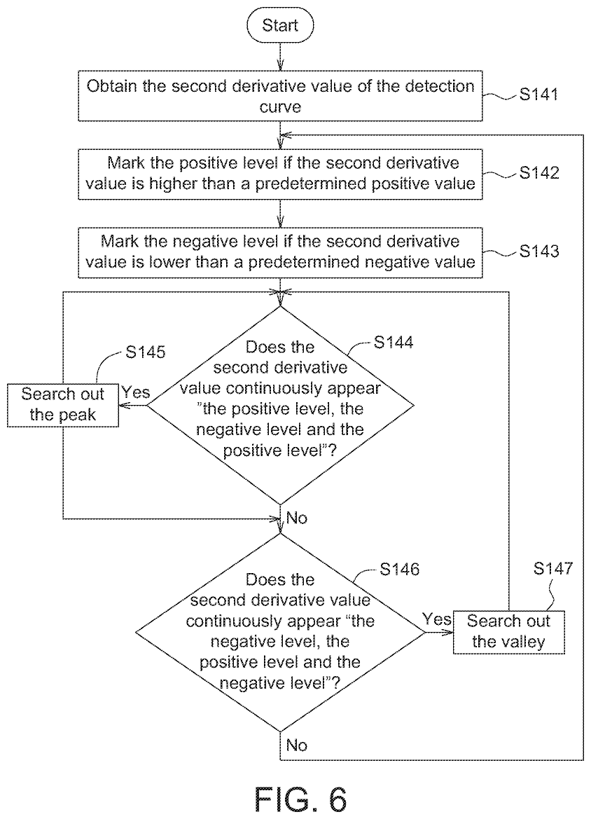

In step S140, the subdivision unit 140 searches out the peak P11 (or P12, P31) or the valley V21 (or V22, V41) in each of the process segments RS51 to RS54 according to the second derivative value Diff2 of the detection curve C5. Please refer to FIGS. 1 and 6. FIG. 6 shows a detailed flowchart of step S140. The subdivision unit 140 includes a differentiator 141, a positive level marker 142, a negative level marker 143 and a finder 144. The step S140 includes steps S141 to S147. In step S141, the differentiator 141 obtains the second derivative value Diff2 of the detection curve C5.

Next, in step S142, the positive level marker 142 marks the positive level PL if the second derivative value Diff2 is higher than a predetermined positive value (for example, 0.5, 0.05, or 0.0005).

Then, in step S143, the negative level marker 143 marks the negative level NL if the second derivative value Diff2 is lower than a predetermined negative value (for example, −0.5, −0.05, or −0.0005). Step S142 and step S143 are interchangeable.

Then, in steps S144 to S147, the finder 144 searches out the peak P11 (or P12, P31) or the valley V21 (or V22, V41) according to the change of the positive level PL and the negative level NL.

In step S144, the finder 144 determines whether the second derivative value Diff2 continuously appears “the positive level PL, the negative level NL and the positive level PL.” If the second derivative value Diff2 continuously appears “the positive level PL, the negative level NL and the positive level PL”, then the process proceeds to step S145. In step S145, the finder 144 searches out the peak P11 (or P12, P31). Taking FIG. 5A as an example, two “the positive level PL, the negative level NL and the positive level PL” are continuously appeared in the process segment RS52, so two peaks P11 and P12 are searched out.

In step S146, the finder 144 determines whether the second derivative value Diff2 continuously appears “the negative level NL, the positive level PL and the negative level NL.” If the second derivative value Diff2 continuously appears “the negative level NL, the positive level PL and the negative level NL”, then the process proceeds to step S147. In step S147, the finder 144 searches out the valley V21 (or V22, V41). Taking FIG. 5B as an example, two “the negative level NL, the positive level PL and the negative level NL” are continuously appeared in the process segment RS52, so two valleys V21 and V22 are searched out.

The above steps S146, S147 can be performed before steps S144, S145.

Then, the process returns to step S145 of FIG. 2. In step S150, the merging unit 150 automatically merges adjacent sub-step segments with the same track type.

Then, in step S160, the analyzing unit 160 performs the Fault Detection and Classification (FDC) with these sub-step segments to obtain the analysis result RS. In this step, for example, the start time, the end time, the track type and other information of the sub-step segments obtained above are compared with an ideal curve to analyze the difference and the degree of difference.

Then, in step S170, the outputting unit 170 outputs the predicted health information PH of the manufacturing equipment 900 based on the analysis result RS.

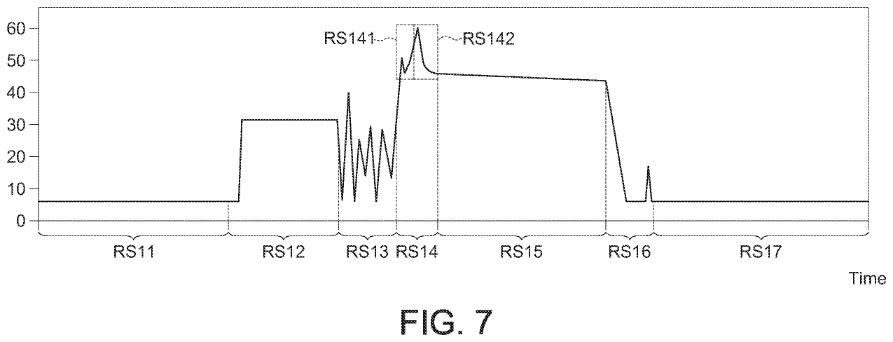

Please refer to FIG. 7, which shows a schematic diagram of the detection curve C1 of FIG. 3 subdivided into sub-step segments RS141, RS142. Through the above automatic detecting method, the process segment RS14 is subdivided into two sub-step segments RS141, RS142. Both the sub-step segments RS141 and RS142 record their start time, end time and track type. In other words, the detection curve C1 can be extracted with more features, so that the accuracy of the Fault Detection and Classification (FDC) can be improved, and then the Prognostic and Health Management (PHM) and the Virtual Metrology (VM) can be more efficiently achieved.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. An automatic detecting method of a manufacturing equipment, comprising:
obtaining a detection curve of the manufacturing equipment executing a plurality of recipe steps;
aligning the detection curve to the recipe steps, such that the detection curve is divided into a plurality of process segments;
searching at least one peak or at least one valley in each of the process segments, to obtain a plurality of sub-step segments;
performing a Fault Detection Classification analysis (FDC), according to the sub-step segments, to obtain an analysis result; and
outputting a predict health information of the manufacturing equipment based on the analysis result.

2. The automatic detecting method of the manufacturing equipment according to claim 1, wherein in the step of searching the peak or the valley in each of the process segments, the peak or the valley is searched according to a second derivative value of the detection curve.

3. The automatic detecting method of the manufacturing equipment according to claim 2, wherein the step of searching the peak or the valley in each of the process segments, to obtain the sub-step segments incudes:
obtaining the second derivative value of the detection curve;
marking a positive level, if the second derivative value is higher than a predetermined positive value;
marking the negative level, if the second derivative value is lower than a predetermined negative value; and
searching out the peak or the valley according to a change of the positive level and the negative level.

4. The automatic detecting method of the manufacturing equipment according to claim 3, wherein if the second derivative value continuously appears the positive level, the negative level and the positive level, then the peak is searched out.

5. The automatic detecting method of the manufacturing equipment according to claim 3, wherein if the second derivative value continuously appears the negative level, the positive level and the negative level, then the valley is searched out.

6. The automatic detecting method of the manufacturing equipment according to claim 3, wherein the predetermined positive value is 0.5 and the predetermined negative value is −0.5.

7. The automatic detecting method of the manufacturing equipment according to claim 1, further comprising:
automatically merging adjacent sub-step segments with identical track type.

8. An automatic detecting device of a manufacturing equipment, comprising:
a data collection unit, configured to obtain a detection curve of the manufacturing equipment executing a plurality of recipe steps;
a mapping unit, configured to align the detection curve to the recipe steps, such that the detection curve is divided into a plurality of process segments;
a subdivision unit, configured to search at least one peak or at least one valley in each of the process segments, to obtain a plurality of sub-step segments;
an analyzing unit, configured to perform a Fault Detection Classification analysis (FDC), according to the sub-step segments, to obtain an analysis result; and
an outputting unit, configured to output a predict health information of the manufacturing equipment based on the analysis result.

9. The automatic detecting device of the manufacturing equipment according to claim 8, wherein the subdivision unit searches out the peak or the valley according to a second derivative value of the detection curve.

10. The automatic detecting device of the manufacturing equipment according to claim 9, wherein the subdivision unit includes:
a differentiator, configured to obtain the second derivative value of the detection curve;
a positive level marker, configured to mark a positive level, if the second derivative value is higher than a predetermined positive value;
a negative level marker, configured to mark the negative level, if the second derivative value is lower than a predetermined negative value; and
a finder, configured to search out the peak or the valley according to a change of the positive level and the negative level.

11. The automatic detecting device of the manufacturing equipment according to claim 10, wherein if the second derivative value continuously appears the positive level, the negative level and the positive level, then the finder searches out the peak.

12. The automatic detecting device of the manufacturing equipment according to claim 10, wherein if the second derivative value continuously appears the negative level, the positive level and the negative level, then the finder searches out the valley.

13. The automatic detecting device of the manufacturing equipment according to claim 10, wherein the predetermined positive value is 0.5 and the predetermined negative value is −0.5.

14. The automatic detecting device of the manufacturing equipment according to claim 8, further comprising:
a merging unit, configured to automatically merge adjacent sub-step segments with identical track type.
